(19) United States
(12) Patent Application Publication
(10) Pub. No.: US 2024/0246293 A1
(43) Pub. Date: Jul. 25, 2024

(54) TECHNIQUES FOR ADDITIVE FABRICATION UTILIZING LCD AND/OR LED LIGHT SOURCES AND RELATED SYSTEMS AND METHODS

(71) Applicant: Formlabs, Inc., Somerville, MA (US)

(72) Inventors: Andrew M. Goldman, Stow, MA (US); Thomas Orr, Cambridge, MA (US); Dmitri Megretski, Carlisle, MA (US); Sung Sik Woo, Billerica, MA (US); Jonathan E. Evans, Somerville, MA (US); Daniel Viner, Somerville, MA (US); Alec B. Rudd, Medford, MA (US); Maxim Lobovsky, Cambridge, MA (US); Graham L. Medlin, Durham, NC (US); Hayley C. Whelan, Somerville, MA (US)

(21) Appl. No.: 18/420,626

(22) Filed: Jan. 23, 2024

Related U.S. Application Data
(60) Provisional application No. 63/440,733, filed on Jan. 24, 2023.

(51) Int. Cl. B29C 64/282; B29C 64/129; B29C 64/268; B29C 64/286; B33Y 10/00; B33Y 30/00; G02F 1/1335; G02F 1/13357; H01L 25/075

(52) U.S. Cl. CPC B29C 64/282; B29C 64/129; B29C 64/268; B29C 64/286; G02F 1/133536; G02F 1/133548; G02F 1/133603; H01L 25/0753; B33Y 10/00; B33Y 30/00

(57) ABSTRACT

An improved additive fabrication device includes a build platform, a vessel designed to hold a liquid photopolymer, and an optical system featuring a micro-LED panel. The micro-LED panel, comprising multiple pixels, projects actinic energy toward the photopolymer in the vessel. The panel selectively activates pixels according to a mask pattern, enabling precise control over the fabrication process. This innovative device offers a streamlined approach to additive manufacturing, utilizing advanced optical technology for efficient and accurate production of complex structures.

### FIELD OF INVENTION

The present invention relates generally to systems and methods for improving 3D printing efficiency and accuracy utilizing LCD and/or LED technology.

### BACKGROUND

Additive fabrication, e.g., 3-dimensional (3D) printing, provides techniques for fabricating objects, typically by causing portions of building material to solidify at specific positions. Additive fabrication techniques may include stereolithography, selective or fused deposition modeling, direct composite manufacturing, laminated object manufacturing, selective phase area deposition, multi-phase jet solidification, ballistic particle manufacturing, particle deposition, laser sintering or combinations thereof. Many additive fabrication techniques build parts by forming successive layers, which are typically cross-sections of the desired object. Typically each layer is formed such that it adheres to either a previously formed layer or a build surface upon which the object is built.

In one approach to additive fabrication, known as stereolithography (SLA) or inverted stereolithography, solid objects are created by successively curing thin solid layers of a curable liquid photopolymer (e.g., a liquid photopolymer resin), typically first onto a build surface and then one on top of another. Exposure to actinic radiation cures a thin layer of photopolymer, which causes it to harden and adhere to previously cured layers and/or to a print substrate (i.e., film layer).

### SUMMARY

The present disclosure relates to techniques for improving the optical performance in SLA-based additive fabrication (also referred to herein as “3D printing”) with a micro-LED panel (also referred to herein as a uLED panel or a LED panel). A micro-LED panel is an LED panel with individual pixels with the size in the range of micrometers, from sub-micrometers to a few micrometers, or to dozens of micrometers. They are significantly smaller than the size of a pixel on a typical LED, which measure in millimeters. Moreover, in a typical LED display the LEDs form a backlight, which is then allowed to pass through, or by blocked by, pixels of an LCD that act like a shutter. In contrast, in a micro-LED display, each pixel comprises its own light source that can be activated or deactivated independently of the light sources of other pixels.

According to some aspects, the techniques described herein relate to an additive fabrication device including: a build platform; a vessel configured to hold a liquid photopolymer; and an optical system including a micro-LED panel configured to emit actinic radiation onto the liquid photopolymer held by the vessel according to a mask pattern, wherein the micro-LED panel includes a plurality of pixels including a respective micro-LED configured to be independently operated to emit actinic radiation.

According to some aspects, the techniques described herein relate to a method of additive fabrication performed by an additive fabrication device including a build platform, a vessel, an optical system including a micro-LED panel including a plurality of pixels including a respective micro-LED configured to be independently operated to emit actinic radiation, the method including: positioning the build platform proximate to the vessel; depositing a liquid photopolymer into the vessel; operating one or more pixels of the plurality of pixels to emit light onto the liquid photopolymer in the vessel, according to a mask pattern, thereby curing a portion of the liquid photopolymer in the vessel according to the mask pattern to form a layer of a three-dimensional object on the build platform.

According to some aspects, the techniques described herein relate to at least one non-transitory computer-readable medium storing instructions that, when executed by a processor, cause an additive fabrication device to perform a method of additive fabrication, wherein the additive fabrication device includes an optical system with a micro-LED panel including a plurality of pixels, the method including: positioning a build platform; filling a vessel with a liquid photopolymer; activating pixels of the plurality of pixels according to a mask pattern; projecting actinic energy from the activated pixels toward the liquid photopolymer in the vessel; and solidifying the liquid photopolymer in the vessel according to the mask pattern to form a three-dimensional object on the build platform.

According to some aspects, the techniques described herein relate to an additive fabrication device including: a build platform; a vessel configured to hold a liquid photopolymer, wherein the vessel includes a bottom surface transparent to at least a first wavelength of light; a backlight illumination system including a plurality of fully addressable LEDs, wherein: each of the fully addressable LEDs is configured to be independently turned on and off, and the fully addressable LEDs are configured to project actinic energy through the bottom surface of the vessel to cure selected regions of the liquid photopolymer in the vessel; and an LCD screen arranged between the backlight illumination system and the bottom surface of the vessel, the LCD screen configured to selectively pass through light generated by the backlight illumination system towards the vessel.

According to some aspects, the techniques described herein relate to a method for fabricating an object using an additive fabrication device, the method including: placing a build platform in the additive fabrication device; filling a vessel with a liquid photopolymer, wherein the vessel includes a bottom surface transparent to at least a first wavelength of light; operating a backlight illumination system including a plurality of fully addressable LEDs, wherein: each of the fully addressable LEDs is independently turned on and off, and the fully addressable LEDs project actinic energy through the bottom surface of the vessel to cure selected regions of the liquid photopolymer in the vessel; and controlling an LCD screen arranged between the backlight illumination system and the bottom surface of the vessel, the LCD screen selectively passing through light generated by the backlight illumination system towards the vessel, wherein the selective passing of light corresponds to a pattern for forming a layer of the object.

According to some aspects, the techniques described herein relate to a computer-readable medium storing instructions that, when executed by a processor, cause the processor to control an additive fabrication device to perform a method for fabricating an object, the method including: placing a build platform in the additive fabrication device; filling a vessel with a liquid photopolymer, wherein the vessel includes a bottom surface transparent to at least a first wavelength of light; operating a backlight illumination system including a plurality of fully addressable LEDs, wherein: each of the fully addressable LEDs is independently turned on and off, and the fully addressable LEDs project actinic energy through the bottom surface of the vessel to cure selected regions of the liquid photopolymer in the vessel; and controlling an LCD screen arranged between the backlight illumination system and the bottom surface of the vessel, the LCD screen selectively passing through light generated by the backlight illumination system towards the vessel, wherein the selective passing of light corresponds to a pattern for forming a layer of the object.

According to some aspects, the techniques described herein relate to an additive fabrication device including: a build platform; a vessel configured to hold a liquid photopolymer; a backlight illumination system configured to project actinic energy onto the liquid photopolymer and thereby cure selected regions the photopolymer; an LCD screen arranged between the backlight illumination system and the vessel configured to selectively pass portions of actinic energy projected by the backlight illumination system, wherein the LCD screen includes a first polarizer on a first surface and a second polarizer on a second surface; and a third polarizer arranged between the backlight illumination system and the first polarizer of the LCD screen.

According to some aspects, the techniques described herein relate to an additive fabrication device including: a build platform; a vessel configured to hold a liquid photopolymer; a backlight illumination system configured to project actinic energy onto the liquid photopolymer and thereby cure selected regions the photopolymer; an LCD screen arranged between the backlight illumination system and the vessel configured to selectively pass portions of actinic energy projected by the backlight illumination system, wherein the LCD screen includes a second polarizer on a second surface; and a third polarizer arranged between the backlight illumination system and the second polarizer of the LCD screen.

The details of one or more implementations of the disclosure are set forth in the accompanying drawings and the description below. Other aspects, features, and advantages will be apparent from the description and drawings, and from the claims.

### BRIEF DESCRIPTION OF DRAWINGS

Various aspects and examples will be described with reference to the following figures. It should be appreciated that the figures are not necessarily drawn to scale. In the drawings, each identical or nearly identical component that is illustrated in various figures is represented by a like numeral. For purposes of clarity, not every component may be labeled in every drawing.

FIG. 1A shows a perspective view of an example additive fabrication system, where the system is arranged in an initial configuration.

FIG. 1B shows a perspective view of an example additive fabrication system, where the system is arranged in a fabricating configuration.

FIG. 1C shows a perspective view of an example additive fabrication system, where the system is arranged in a finished configuration.

FIG. 2A depicts an improved additive fabrication system with a micro-LED panel.

FIG. 2B depicts an improved additive fabrication system with a micro-LED panel and a lens array.

FIG. 3A depicts an improved additive fabrication system with an LED panel, an LCD screen, and a pre-polarizer.

FIG. 3B depicts an improved additive fabrication system with an LED panel, an LCD screen, and a polarizing beam-splitter.

FIG. 4 depicts an improved additive fabrication system with an LED array and an LCD screen.

FIG. 5 is a block diagram of a system suitable for practicing aspects of the invention, according to some embodiments.

### DETAILED DESCRIPTION

As described above, stereolithography printers generally include a vessel containing a photocurable liquid (e.g., a photopolymer resin) that is cured when light is incident on the liquid, where the light is typically in the near UV wavelength (e.g., 365-405 nm, predominantly at 405 nm). Historically, lasers were used for light delivery, but in recent years, area projection technologies such as Digital Light Processing (DLP), Digital Micromirror Device (DMD), and Liquid Crystal Display (LCD) have also been used for light delivery. LCD optical systems consist of a UV backlight that transmits light through an LCD screen from the display industry that is used as a spatial mask to trace out the geometry of each layer of the model to be printed, layer-by-layer.

Two important optical performance parameters for SLA are optical intensity and contrast ratio. A higher optical intensity allows for faster printing, and a higher contrast ratio allows for crisper prints. Typical SLA wavelengths are from 365 nm to 415 nm. At these wavelengths, DLP and LCD suffer from poor optical efficiency. This means that achieving a high optical intensity has a comparatively high energy demand, which also produces thermal management challenges. In addition, the contrast ratio is poor, typically in the hundreds to one. Liquid Crystal Displays also degrade with heat and UV exposure, sometimes resulting in poor lifetimes.

Therefore, an optical system that improves both optical efficiency and contrast ratio is highly desirable.

Historically, stereolithography (SLA) 3D printing, where a liquid photopolymer is cured layer by layer to produce a 3D part, was accomplished by steering a laser beam in the appropriate pattern for each layer. As 3D printing has become a more useful digital fabrication method, users are more likely to fill the print area than previously. Print speed becomes limited with a beam steered laser as more print area is utilized per layer. In recent times, some 3D printers have shifted to using display technologies, such as DLP or LCD, as an area projection method in order to increase print speed for parts with high print area utilization.

Typical SLA wavelengths are from 365 nm to 415 nm. At these wavelengths, DLP and LCD suffer from poor optical efficiency. This means that achieving a high optical intensity is costly and a thermal management challenge. Likewise, the contrast ratio is poor, typically in the hundreds to one. Liquid Crystal degrades with heat and UV exposure, sometimes resulting in poor lifetime for LCD systems.

To address these problems, the disclosed invention uses a uLED panel as an optical system for SLA 3D printing. Optical efficiency is significantly improved, leading to higher optical intensity at lower cost and easier thermal management, and contrast ratio is improved by an order of magnitude or more. LEDs will degrade over time, but at a significantly lower rate than LCD.

Following below are more detailed descriptions of various concepts related to, and implementations of, techniques for utilizing a micro-LED display in additive fabrication. It should be appreciated that various aspects described herein may be implemented in any of numerous ways. Examples of specific implementations are provided herein for illustrative purposes only. In addition, the various aspects described in the implementations below may be used alone or in any combination, and are not limited to the combinations explicitly described herein.

Hereinafter, a photopolymer resin may be referred to as an illustrative photopolymer, however it will be appreciated that this type of material is provided as an example and that the techniques described herein are not limited to particular types of liquid photopolymers, and may be applied to non-resin liquid photopolymers.

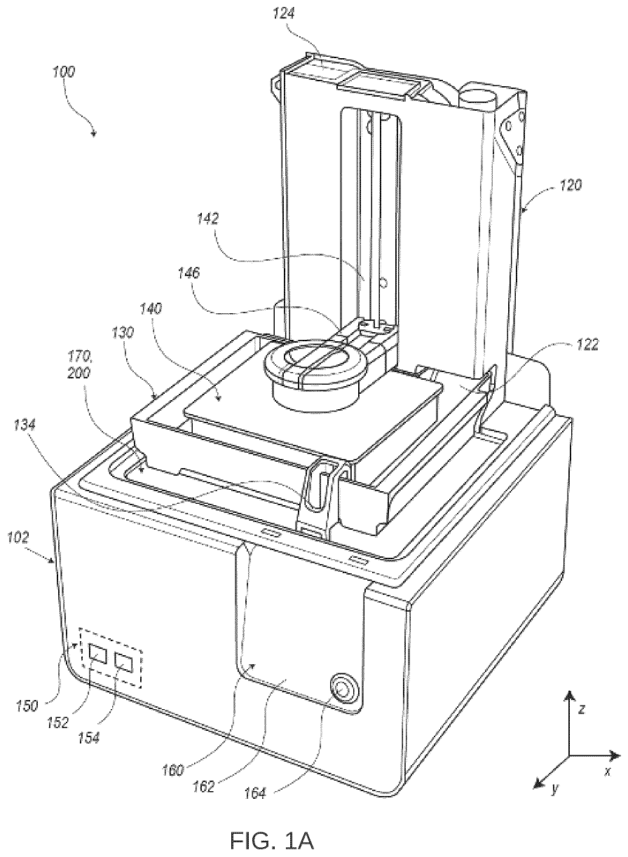

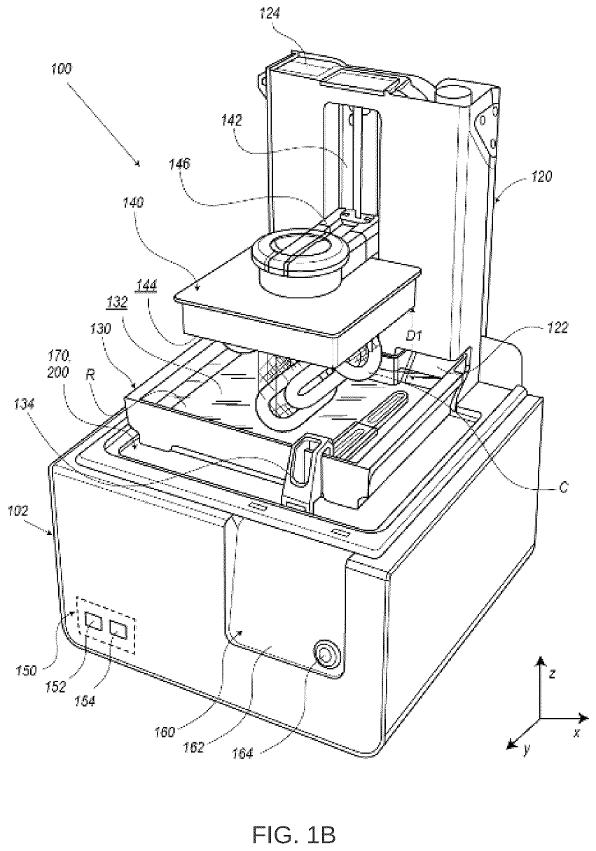

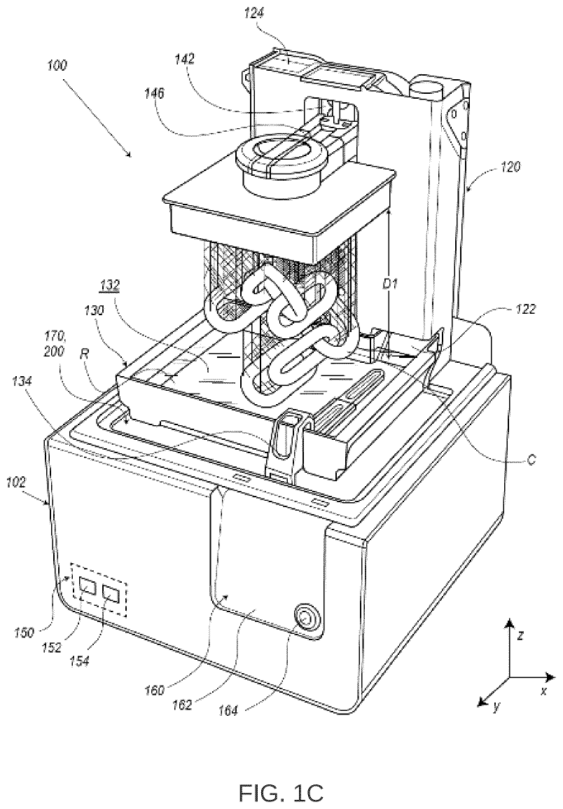

Referring to FIGS. 1A-1C, an additive fabrication device 100, such as a stereolithographic printer, includes a base 102 and a dispensing system 120 coupled to the base 102. The base 102 supports a fluid basin 130 configured to receive a photopolymer resin from the dispensing system 120. The printer 100 further includes a build platform 140 positioned above the fluid basin 130 and operable to traverse a vertical axis (e.g., z-axis) between an initial position (FIG. 1A) adjacent to a bottom surface 132 of the fluid basin 130 and a finished position (FIG. 1C) spaced apart from the bottom surface 132 of the fluid basin 130.

The base 102 of the printer 100 may house various mechanical, optical, electrical, and electronic components operable to fabricate objects using the device. In the illustrated example, the base 102 includes a computing system 150 including data processing hardware 152 and memory hardware 154. The data processing hardware 152 is configured to execute instructions stored in the memory hardware 154 to perform computing tasks related to activities (e.g., movement and/or printing based activities) for the printer 100. Generally speaking, the computing system 150 refers to one or more locations of data processing hardware 152 and/or memory hardware 154. For example, the computing system 150 may be located locally on the printer 100 or as part of a remote system (e.g., a remote computer/server or a cloud-based environment).

The base 102 may further include a control panel 160 connected to the computing system 150. The control panel 160 includes a display 162 configured to display operational information associated with the printer 100 and may further include an input device 164, such as a keypad or selection button, for receiving commands from a user. In some examples, the display is a touch-sensitive display providing a graphical user interface configured to receive the user commands from the user in addition to, or in lieu of, the input device 164.

The base 102 houses a curing system 170 configured to transmit actinic radiation into the fluid basin 130 to incrementally cure layers of the photopolymer resin contained within the fluid basin 130. The curing system 170 may include a projector or other radiation source configure to emit light at a wavelength suitable to cure the photopolymer resin within the basin. Thus, different light sources may be selected depending on the desired photopolymer resin to be used for fabricating a component C. In the present disclosure, the curing system 170 includes a liquid crystal panel 200 for curing the photopolymer resin within the fluid basin 130.

As shown, the fluid basin 130 is disposed atop the base 102 adjacent to the curing system 170 and is configured to receive a supply of the resin R from the dispensing system 120. The dispensing system 120 may include an internal reservoir 124 providing an enclosed space for storing the resin until the resin is needed in the fluid basin 130. The dispensing system 120 further includes a dispensing nozzle 122 in communication with the fluid basin 130 to selectively supply the resin R from the internal reservoir 124 to the fluid basin 130.

The build platform 140 may be movable along a vertical track or rail 142 (oriented along the z-axis direction, as shown in FIGS. 1A-1C) such that base-facing build surface 144 of the build platform 140 is positionable at a target distance D1 along the z-axis from the bottom surface 132 of the fluid basin 130. The target distance D1 may be selected based on a desired thickness of a layer of solid material to be produced on the build surface 144 of the build platform 140 or onto a previously formed layer of the object being fabricated. In some implementations, the build platform 140 is removable from the printer 100. For instance, the build platform 140 may be attached to the rail 142 by an arm 146 (e.g., pressure fit or fastened onto) and may be selectively removed from the printer 100 so that a fabricated component C attached to the build surface 144 can be removed via the techniques described above.

In the example of FIGS. 1A-1C, the bottom surface 132 of basin 130 may be transparent to actinic radiation that is generated by the curing system 170 located within the base 102, such that liquid photopolymer resin located between the bottom surface 132 of the basin 130 and the build surface 144 of the build platform 140 or an object being fabricated thereon, may be exposed to the radiation. Upon exposure to such actinic radiation, the liquid photopolymer may undergo a chemical reaction, sometimes referred to as “curing,” that substantially solidifies and attaches the exposed resin to the build surface 144 of the build platform 140 or to a bottom surface of an object being fabricated thereon.

Following the curing of a layer of the fabrication material, the build platform 140 may incrementally advance upward along the rail 142 in order to reposition the build platform 140 for the formation of a new layer and/or to impose separation forces upon any bond with the bottom surface 132 of basin 130. In addition, the basin 130 is mounted onto the support base such that the printer 100 may move the basin 130 along a horizontal axis of motion (e.g., x-axis), the motion thereby advantageously introducing additional separation forces in at least some cases. A wiper 134 is additionally provided, capable of motion along the horizontal axis of motion and which may be removably or otherwise mounted onto the base 102 or the fluid basin 130.

With continued reference to FIGS. 1A-1C, the printer 100 is shown at different stages of the fabrication process. For example, at FIG. 1A, the printer is shown in an initial state prior to dispensing the resin R into the basin 130 from the reservoir 124 of the dispensing system 120. Upon receipt of fabrication instructions, the printer 100 positions the build surface 144 of the build platform 140 at an initial distance D1 from the bottom surface 132 of the basin 130 corresponding to a thickness of the first layer of resin R to be cured. The curing system 170 then emits an actinic radiation profile (i.e., an image) corresponding to the profile of the current layer of the component C to cure the current layer. Upon curing of the current layer, the build platform 140 incrementally advances upward to the next build position. The distance of each advancement increment corresponds to a thickness of the next layer to be fabricated. The curing system 170 then projects the profile of the component layer corresponding to the new position. The new component layer is cured on a bottom surface of the previous component layer. The curing and advancing steps repeat until the build platform 140 reaches the final position (FIG. 1C) corresponding to the finished component C.

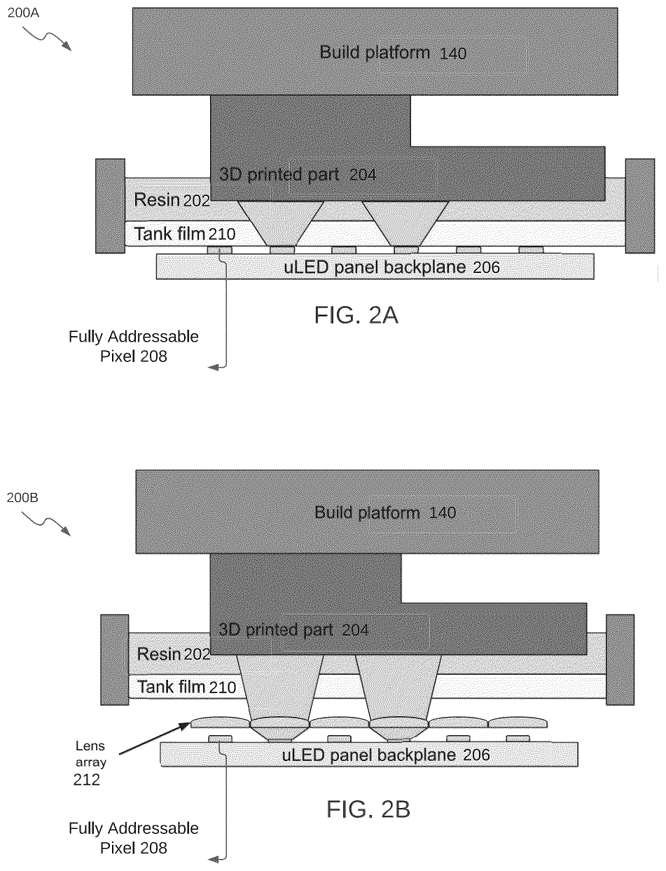

FIGS. 2A-2B illustrates the first aspect of the present invention relating to an additive fabrication device for creating three-dimensional objects. The device comprises a build platform, a vessel for retaining photopolymer, and an optical system including a micro-LED panel, where the pixel size is from a fraction of a micron to a few microns.

The build platform serves as the base upon which the object is constructed. It can be made of various materials such as aluminum, steel, or glass, depending on the application and the properties of the final object. The build platform can also be heated or cooled to control the curing process of the photopolymer.

The vessel is configured to hold the liquid photopolymer, which is a liquid that at least partially solidifies (also referred to herein as being “cured” or “curing”) when exposed to specific types of light. The bottom of the vessel can be made of transparent materials such as glass, acrylic, or polycarbonate, to allow the light to pass through and reach the resin. The vessel can also be sealed to prevent the resin from drying out or being contaminated before the fabrication process starts.

The optical system, consisting of a micro-LED panel, projects light into the vessel to solidify the resin in a specific pattern according to the received mask pattern. The micro-LED panel is a specialized type of LED panel that is able to selectively turn on individual pixels. References to “turning on” a pixel of a micro-LED panel refer to operating the pixel to emit light. As such, selectively turning on an individual pixel refers to operating the pixel to emit light independently of whether any other pixels in the micro-LED panel are also operated in the same way. An array of pixels that can be independently selectively turned on is capable of producing any desired combination or pattern of pixels in which some are turned on and the rest are turned off. Because each pixel in the micro-LED panel comprises a micro-LED that can be operated as an independent light source, this approach allows for precise control over the amount of light that is projected into the vessel and the pattern in which it is projected. The received mask pattern is used to determine which pixels of the micro-LED panel should be turned on and off during the fabrication process.

The micro-LED panel can be controlled by a microcontroller or a computer that receives the mask pattern from 3D modeling software. The mask pattern can be generated by slicing a 3D model into layers and creating a pattern for each layer. The device can also include sensors and feedback systems to monitor the process, such as temperature, humidity, and curing progress.

In operation, the device deposits liquid photopolymer into the vessel. The optical system is then activated, and the micro-LED panel projects light into the vessel according to the received mask pattern. The light solidifies the resin in the pattern defined by the mask, creating a layer of the three-dimensional object on the build platform. The process is repeated, layer by layer, until the object is fully formed.

The additive fabrication device of the present invention has several advantages over traditional manufacturing methods. It can create highly detailed and complex objects, with a high degree of accuracy and repeatability. The device can also work with a wide range of materials, such as photopolymers, composites, and ceramics.

The device can also be used for a variety of applications, such as prototyping, tooling, jewelry, dental and medical implants, and even aerospace and automotive parts. The device can also be adapted to different scales, from small tabletop devices to large industrial systems.

In summary, the present invention is an additive fabrication device that uses a micro-LED panel to selectively solidify photopolymer in a specific pattern, as determined by a received mask pattern, to create three-dimensional objects on a build platform. The device offers high precision, repeatability, and versatility, and can be used in various fields such as prototyping, tooling, jewelry, dental and medical implants, aerospace, and automotive parts.

In some embodiments, the micro-LED panel is configured to produce light with a wavelength between 365 nm and 415 nm.

In some embodiments, the vessel includes a transparent bottom surface to the actinic energy projected by the micro-LED panel, and the micro-LED panel is placed in direct contact with the bottom surface of the vessel.

In some embodiments, a protective glass is placed between the micro-LED panel and the bottom of the vessel.

In some embodiments, one or more intermediate optics or apertures are placed between the micro-LED panel and the bottom surface of the vessel.

In some embodiments, the optics are refractive optics, Fresnel-type optics, or diffractive optics.

In some embodiments, the micro-LED panel is placed above the vessel.

FIG. 2A depicts an improved additive fabrication system 200A with a fully addressable micro-LED (uLED) panel 206 (also known as a uLED display or uLED panel backplane). The uLED panel 206 serves as the light source for the SLA 3D printing process. In some embodiments, the uLED panel 206 includes a large array of fully addressable LED pixels 208, each of which can be controlled independently. As a result, the additive fabrication system 200A, via a microcontroller or an LED driver, can specify the color, brightness, state, and/or other properties of each LED pixel 208 individually. The fully addressable uLED panel 206 provides the flexibility to adapt the pixel illumination in accordance with the 3D model's specifications, such as creating an illumination pattern that corresponds to the cross-section of the 3D model that is being printed.

In some embodiments, the LED pixels 208 have sizes from a fraction of a micron to hundred of microns (0.1 um-1000 um). In some embodiments, the uLED panel 206 is larger than or equal to the entire printing area of the build platform 140.

In addition to improved accuracy, the fully addressable uLED panel 206 allows for the implementation of variable curing strategies. For example, by individually adjusting the brightness, exposure time, and/or other optical properties of the LED pixels 208, the additive fabrication system 200A can control the curing depth and degree of cross-linking in the resin. This enables the creation of objects with varying mechanical properties, such as stiffness or flexibility, within the same print job.

In some implementations, the additive fabrication system 200A selectively cures multiple layers in a single exposure for certain regions of the 3D printed part 204, while cure other regions one layer at a time. For example, in regions where multiple layers can be cured simultaneously, the system can increase the exposure time and brightness of the corresponding LED pixels 208, allowing the light to penetrate deeper into the resin 202 and cure multiple layers at once. An advantage of this selective, multi-layer curing approach is the reduction in the number of peel steps required during the printing process. As the peeling of layers is a time-consuming aspect of SLA 3D printing, minimizing the number of peel steps can lead to significant time savings. By curing multiple layers simultaneously in certain regions, the overall number of layers that need to be individually peeled and separated from the build platform is reduced, leading to a faster and more efficient printing process.

In some embodiments, the additive fabrication system 200A incorporates a feedback mechanism, such as a camera or a sensor, to monitor the printing process and provide real-time data to the controlling computer. This data can be utilized to make necessary adjustments to the LED pixel 208 settings, ensuring optimal performance and print quality throughout the entire process. Furthermore, the dynamic control of the uLED panel 206 enables real-time adjustments during the printing process. For instance, if the system detects an issue with the current layer, such as an incomplete cure or a print defect, it can immediately adjust the LED pixel 208 settings to compensate for the error, potentially reducing the overall print time and material waste.

In some embodiments, the uLED panel 206 consists of a GaN LED array emitting blue or near-blue light (˜450 nm) on backplane technology configured for fully addressable pixel brightness and frame rates of 30 Hz to 120 Hz. The blue light array both acts as a direct source for blue pixels as well as a pump for green and red pixels; the green and red wavelengths typically achieved using quantum dots.

In some embodiments, the GaN LEDs are doped to lower center wavelengths, such as those suitable for SLA 3D printing (e.g., 365 nm-415 nm). Doping the GaN LEDs helps to lower the center wavelengths, making these LED pixels more suitable for 3D printing applications. The uLED panel 206 is doped for the desired wavelength, and the quantum dot layer for achieving green and red wavelengths are removed. For example, an array of 405 nm LEDs at 50 um pitch on a backplane capable of displaying images at >30 Hz.

The pixel size at the tank/resin interface plays a crucial role in determining the fine features and resolution performance of the 3D printed part 204. The pixel size projected on the tank/resin interface is a function of the LED pixel size, tank film thickness, tank film index of refraction, LED emission angle at the tank/resin interface, etc. LEDs emit a Lambertian light pattern that expands quickly with any distance from the light source. This expansion can cause a loss of resolution and sharpness in the printed object. To overcome the divergence of light and maintain high-resolution printing, it is desirable to have a small projected pixel size of the uLED panel 206 at the resin/film interface.

As illustrated in FIG. 2A, in some embodiments, the uLED panel 206 is placed in close proximity to the tank film 210 and without intermediate optics to minimize the light divergence effect. For example, each LED pixel 208 is within a few millimeter distance from the bottom of the tank film (e.g., <10 mm). This close proximity allows for better control over the curing process, which, in turn, results in more accurate and detailed 3D printed parts. In these embodiments, the uLED panel 206 can be held in place using spacers or other positioning mechanisms to ensure uniform distance across the entire panel.

In other embodiments, the uLED panel 206 is placed in direct contact with the tank film 210, reducing the distance between the light source and the resin/film interface even further. This arrangement allows for a more focused light pattern, potentially enhancing the precision of the printing process.

Alternatively, the tank film 210 can be laminated over the uLED panel 206, creating a seamless integration between the light source and the tank film 210. This lamination can be achieved using optically clear materials that maintain the transmission of light from the uLED panel 206 to the resin 202. By laminating the tank film 210 directly onto the uLED panel 206, the optical system achieves an even more compact design and further minimizes light divergence, leading to improved resolution and fine feature reproduction in the 3D printed parts.

In addition, the uLED panel 206 significantly improves contrast ratio of the 3D printing process. Traditionally, LCDs are driven by polarizer extinction ratio, and liquid crystal polarization degrees, typically on the order of hundred to one. In DLP technology, there is a direct tradeoff between the numerical aperture of the projection lens (which drives optical efficiency and optical intensity) and contrast ratio. Typically hundred to one. In uLED technology, on the other hand, any LEDs that are not used in any given layer are simply turned off, resulting in contrast ratio on the order of thousands to one.

Alternatively or optionally, as FIG. 2B depicts, an additive fabrication system 200B includes an lens array 212 (also known as intermediate optics or microlens array) to extend the operating standoff from the uLED panel 206 to the tank film 210.

In some embodiments, the microlens array 212 is a collection of miniature lenses (e.g., less than 1 mm in diameter) arranged in a regular pattern. Each microlens in this array can serve to focus and direct the light emitted by one or more underlying pixels 208 from the uLED panel 206. The microlens array 212 acts as a bridge between the pixels 208 and the tank film 210, channeling the light beams towards their target with heightened precision.

The correspondence between each microlens and its micro pixel(s) is design to optimally focus and direct the light from each micro pixel 212. This can be achieved by matching the lens diameter, shape, and curvature to the characteristics of the light emitted from each micro pixel 212. Furthermore, the microlens array 212 can be designed to provide additional functionality such as beam shaping and homogenization, which can further enhance the performance of the additive fabrication system 200B.

In some examples, the lens array 212 may be refractive, diffractive, Fresnel, etc. Further, there may be a single lens array or multiple lens arrays, apertures, etc., to further shape the beams. The addition of an intermediate optic 212 allows for a protective cover between the pixels 208 and the tank film 210.

While the lens array 212 could potentially be made from a variety of materials, it is typically composed of a material that allows for high optical clarity and precision, such as certain types of glass or plastic. In some embodiments, it is possible to replace the lens array 212 to alter the beam shaping. Alternatively, the lens array 212 is a fixed component of the additive fabrication system 200B.

In some embodiments, the lens array 212 is produced by techniques such as nano-imprinting (e.g., sheet or roll to roll), ion etching, photolithography, and optical replication.

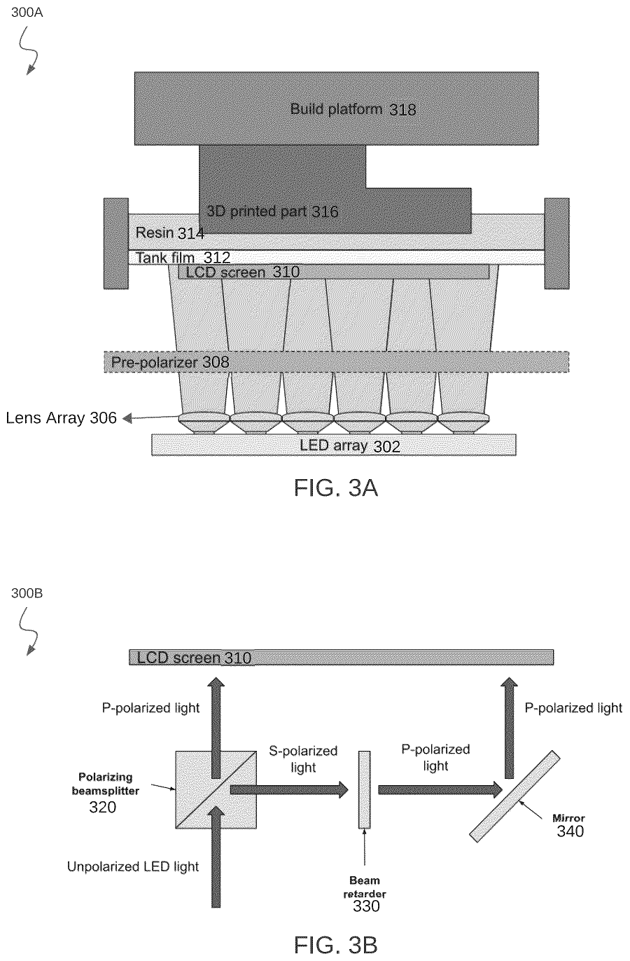

FIGS. 3A-3B illustrates an additive fabrication system 300A with an LED array 302, a pre-polarizer 308, and an LCD screen 310.

In some embodiments, the LED array 302 is a non-addressable LED array, where all LED pixels are connected in parallel and shared the same control signal.

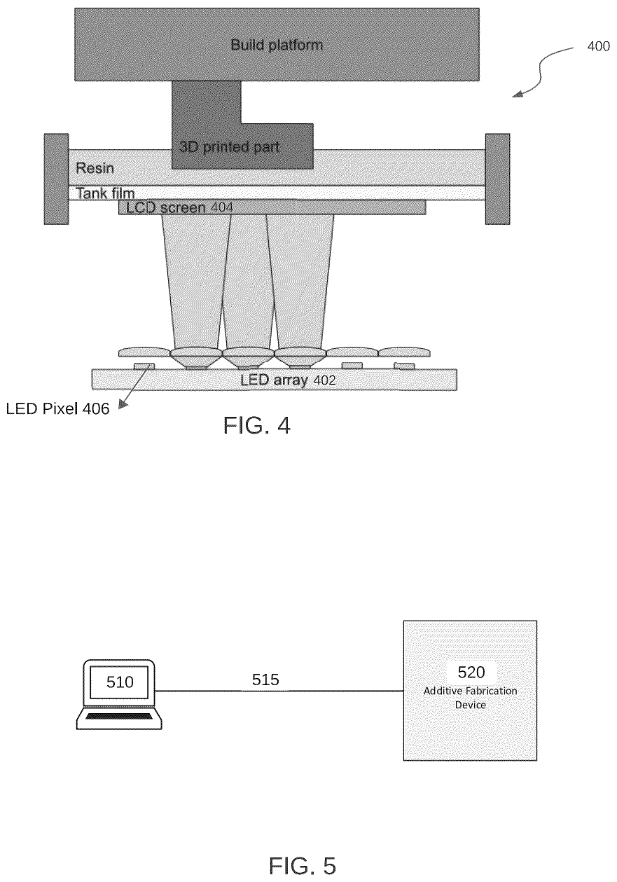

Alternatively, the LED array 302 comprises fully addressable pixel (e.g., similar to the uLED panel backplane 206 in FIG. 2A o FIG. 2B) that are capable of projecting actinic energy capable of curing the resin 314 in the resin tank. Each of the fully addressable LED pixels is configured to be independently turned on and off, which allows for precise control over the amount of light that is projected into the vessel and the pattern in which it is projected. Refer to FIG. 4 and the related description for the configuration of using fully addressable LED array and an LCD.

The LCD screen 310 is located between the LED array 302 and the bottom surface of the tank film 312. The LCD screen 310 is configured to selectively pass through light generated by the LED array 302 toward the resin tank. This configuration allows for a high degree of precision in the curing process by selectively turning on light only at areas corresponding to the cross-section of the 3D printed part 316 (through the fully addressable pixel), and passing light only to specific areas of the vessel (through the LCD screen 310).

In some embodiments, the additive fabrication system 300A also includes sensors and feedback systems to monitor the print process, such as temperature, humidity and curing progress.

In operation, the device first fills the vessel with photopolymer. The backlight illumination system is then activated, and the fully addressable LEDs project light towards the vessel according to the received mask pattern. The LCD screen selectively passes the light through to the vessel, solidifying the resin in the pattern defined by the mask, creating a layer of the three-dimensional object on the build platform. The process is repeated, layer by layer, until the object is fully formed.

In some embodiments, the fully addressable LEDs are controlled by a LED drive current control of up to 16 bits.

FIG. 3A depicts an improved additive fabrication system with an LED panel, an LCD screen, and a pre-polarizer.

In FIG. 3A, the pre-polarizer absorbs all of the cross-polarized light. All of the heat is dissipated in the pre-polarizer and does not reach the LCD screen. The pre-polarizer may be mounted on any appropriate glass or plastic substrate. The pre-polarizer may be an absorptive film type, such as Iodine type or dye type, a wire grid polarizer, a thin film polarizer, etc.

Alternatively, the pre-polarizer can be a reflective polarizer rather than an absorptive polarizer. This accomplishes the same goal of preventing cross-polarized light from getting to the first polarizer on the LCD screen, but has the advantage that it can be laminated to the LCD screen as the first optical surface the LED light hits.

FIG. 3B depicts an improved additive fabrication system 300B that uses a polarizing beam-splitter 320 instead of a pre-polarizer. The additive fabrication system 300B is configured to eliminate cross polarized light before such light reaches the LCD screen 310.

The polarizing beam splitter 320 is used to split the S and P polarized light from each LED source. While the parallel polarized light (P-polarized light) passes through the polarizing beam-splitter 320, the cross polarized light (S-polarized light) is diverted to pass through a beam retarder 330 such that the polarization state is twisted by 90° to become parallel polarized light (P-polarized light), and then is redirected towards the LCD screen 310 (e.g., through a mirror 340). As such, the additive fabrication system 300B is configured to reuse cross polarized light that would otherwise be wasted or absorbed by an absorptive polarizer and converted to heat.

In some embodiments, instead of relying on an LED light source, a laser is used to end only parallel polarized light to the LCD screen 310. Lasers inherently have a single polarization axis, which can be lined up with the first polarizer of the LCD screen 310. Alternatively, super-luminescent diodes (SLDs), which also inherently have a single polarization axis, can be used instead of lasers. In some embodiments, using a laser or a SLD with a sufficient polarization extinction ratio allows the removal of the first polarizer on the LCD screen.

A known issue in utilizing liquid crystal display (LCD) screens for stereolithography (SLA) printing is that LCD screens transmit a non-zero quantity of light even when the pixels are in an inactive state. This undesired transmission of light, colloquially referred to as “leaked” light, can inadvertently solidify the photopolymer resin within the reservoir, thereby detrimentally impacting the quality of the resultant prints and leading to material waste.

The light leakage issue may be substantially mitigated through the provision of an LED array wherein each LED can be controlled individually. By deactivating the LEDs in regions of the print area that are not engaged in the active printing process for each respective layer, the inadvertent solidification of resin may be prevented.

FIG. 4 shows an improved additive fabrication system 400 with an LED array 402 in operative association with an LCD screen 404. In certain embodiments, the LED array 402 comprises a fully-addressable LED array (e.g., similar to those illustrated in FIGS. 2A and 2B), wherein each LED pixel 406 is independently controllable to an on or off state.

The LED array 402 directs actinic energy onto the LCD screen 404, which is designed to selectively permit light to pass through to cure the resin. UV or near-UV light is emitted from the LED array 402, and each LED pixel 406 within the array can be individually controlled by LED driver electronics. When a layer of the 3D object is being printed, only the LED pixels that correspond to the current cross-sectional area of the object are switched on. The rest of the LED pixels are switched off to prevent light from reaching the resin in areas where solidification is not desired. For instance, if the current layer does not require illumination on the far left or far right, the LED pixels in those areas would remain off. This targeted illumination ensures that the resin only solidifies where the object is being built, conserving resin and enhancing print quality.

The fully-addressable LED array 402 and the LCD screen 404 work in tandem to precisely control where and how light is applied to the resin. As the LED array 402 is made up of numerous small LED pixels (e.g., micro LED pixels) that can each be turned on or off independently, the system 400 can create a pattern of light that matches the exact shape of that layer.

The LCD screen 404 then acts as a dynamic mask that works in conjunction with the LED array 402. Each pixel on the LCD screen 404 can either allow light to pass through or block it. When a pixel on the LCD is o′, it becomes transparent and lets the light from the LED array through to cure the resin below in the corresponding shape. When a pixel is off, it remains opaque, blocking the light from the LED array 402 and preventing the resin directly below it from curing.

By coordinating which LEDs are on with which pixels on the LCD screen are transparent, the system can control the light pattern precisely. This allows for the creation of detailed 3D objects with less waste and faster print times. The LED driver electronics play a crucial role in this process by providing the necessary control signals to each LED pixel, ensuring that the light pattern is accurate for each layer of the print.

Below is an example of how the system 400 prints a “ring” object using the LED array 402 and the LCD 404:

As the printing process begins, the system 400 first determines the cross-sectional shape of the ring for the initial layer. For example, this shape is a circle with a hole in the middle.

The system 400 then activates only the LED pixels that are positioned above the area where the ring's outline will be printed. Simultaneously, the LCD screen 404 adjusts its pixels to be transparent (‘on’) only in the shape of the ring's cross-section, while the rest of the pixels remain opaque (‘off’). This coordination ensures that UV light only passes through the LCD screen where the ring shape is to be printed.

As the UV light shines through the transparent pixels of the LCD screen 404, it reaches the resin below, which is contained in the resin tank. The light cures the resin in the exact shape of the ring's cross-section, solidifying it and creating the first layer of the 3D object.

For the subsequent layers, the system 400 continues this precise coordination. The LED array 402 and LCD screen 404 work together to adjust the pattern of light for each new layer, matching the changing cross-sectional shapes as the object is built up layer by layer. If the next layer requires a slightly different shape due to the design of the ring, the LED pixels and LCD pixels will adjust accordingly to ensure that only the corresponding areas are cured.

This precise control over the light pattern allows for intricate details and smooth surfaces on the finished 3D object. The precision can be further improved with smaller size LED pixels, such as the microLED pixels illustrated in FIGS. 2A and 2B. By selectively curing the resin in this manner, the system 400 minimizes the curing of unwanted areas, which would otherwise lead to a loss of detail and accuracy. The result is a more precise and efficiently printed 3D object with less waste of materials and time.

In some embodiments, using individually addressable LEDs enables faster print times. LCD screens 404 let only a small percentage of light through the pixels when the pixels are “off”. There is a threshold of optical intensity where resin solidification is negligible. An alternative to addressable LEDs is to just keep the optical intensity at the resin below this threshold. The optical intensity at the LCD screen 404 can be configured such that the optical intensity at the resin is below the threshold when the LCD pixels are “off”. However, this limits the optical intensity at the resin when the pixels are “on”, which in turn limits how quickly the photopolymer in each layer can be cured, which is a limit to the overall print speed. With addressable LEDs this optical intensity limit at the LCD screen 404 may be ignored because the LEDs are turned off except where the active printing occurs. This means that more optical intensity can be safely applied where the printing occurs, which will result in an increase in overall print speed.

FIG. 5 is a block diagram of a system suitable for practicing aspects of the invention, according to some embodiments. System 500 illustrates a system suitable for generating instructions to perform additive fabrication by a stereolithography device and subsequent operation of the additive fabrication device to fabricate an object. For instance, instructions to fabricate the object using an additive fabrication system may comprise instructions to operate a build platform of an SLA device.

According to some embodiments, computer system 510 may execute software that generates two-dimensional layers that may each comprise sections of the object. Instructions may then be generated from this layer data to be provided to an additive fabrication device, such as additive fabrication device 520, that, when executed by the device, fabricates the layers and thereby fabricates the object. Such instructions may be communicated via link 515, which may comprise any suitable wired and/or wireless communications connection. In some embodiments, a single housing holds the computing device 510 and additive fabrication device 520 such that the link 515 is an internal link connecting two modules within the housing of system 500.

In the present patent application, numerous embodiments and configurations of the device have been illustrated and described in detail through various figures. It should be understood that these embodiments are not intended to be exhaustive or to limit the invention to the precise forms disclosed. Rather, the embodiments and configurations depicted in the figures are chosen and described to best explain the principles of the invention and its practical applications, thereby enabling others skilled in the art to understand the invention for various embodiments and with various modifications as are suited to the particular use contemplated.

It is important to note that the features and aspects of the device shown in one figure can be combined with, or substituted for, the features and aspects of the device shown in another figure. This cross-pollination of embodiments and configurations is intended to provide a comprehensive disclosure of the invention, allowing for a wide range of potential applications and implementations. The various embodiments and configurations described herein are not meant to be mutually exclusive, but rather, they can be combined and adapted in numerous ways to achieve the desired functionality and characteristics of the device.

Furthermore, it is to be understood that the terminology used herein is for the purpose of describing particular embodiments only and is not intended to be limiting. As used in this specification and the appended claims, the singular forms “a,” “an,” and “the” include plural referents unless the context clearly dictates otherwise. Thus, for example, reference to “a configuration” includes a plurality of such configurations and reference to “an embodiment” includes a plurality of such embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An additive fabrication device comprising:
a build platform;
a vessel configured to hold a liquid photopolymer; and
an optical system comprising a micro-LED panel configured to emit actinic radiation onto the liquid photopolymer held by the vessel according to a mask pattern, wherein the micro-LED panel comprises a plurality of pixels comprising a respective micro-LED configured to be independently operated to emit actinic radiation.

2. The additive fabrication device of claim 1, further comprising one or more intermediate optics or apertures arranged between the micro-LED panel and a bottom surface of the vessel.

3. The additive fabrication device of claim 2, wherein the intermediate optics are refractive optics, Fresnel-type optics, or diffractive optics.

4. The additive fabrication device of claim 1, wherein the plurality of pixels of the micro-LED panel are configured to independently emit actinic radiation with a wavelength between 365 nm and 415 nm.

5. The additive fabrication device of claim 1, wherein the vessel includes a bottom surface that is transparent to at least some wavelengths of the actinic radiation projected by the micro-LED panel, and wherein the micro-LED panel is arranged in contact with the bottom surface of the vessel.

6. The additive fabrication device of claim 1, further comprising a protective glass arranged between the micro-LED panel and the vessel.

7. The additive fabrication device of claim 1, wherein the micro-LED panel is arranged below the vessel.

8. A method of additive fabrication performed by an additive fabrication device comprising a build platform, a vessel, an optical system comprising a micro-LED panel including a plurality of pixels comprising a respective micro-LED configured to be independently operated to emit actinic radiation, the method comprising:
positioning the build platform proximate to the vessel;
depositing a liquid photopolymer into the vessel;
operating one or more pixels of the plurality of pixels to emit light onto the liquid photopolymer in the vessel, according to a mask pattern, thereby curing a portion of the liquid photopolymer in the vessel according to the mask pattern to form a layer of a three-dimensional object on the build platform.

9. At least one non-transitory computer-readable medium storing instructions that, when executed by a processor, cause an additive fabrication device to perform a method of additive fabrication, wherein the additive fabrication device comprises an optical system with a micro-LED panel including a plurality of pixels, the method comprising:
positioning a build platform;
filling a vessel with a liquid photopolymer;
activating pixels of the plurality of pixels according to a mask pattern;
projecting actinic energy from the activated pixels toward the liquid photopolymer in the vessel; and
solidifying the liquid photopolymer in the vessel according to the mask pattern to form a three-dimensional object on the build platform.

10. An additive fabrication device comprising:
a build platform;
a vessel configured to hold a liquid photopolymer, wherein the vessel includes a bottom surface transparent to at least a first wavelength of light;
a backlight illumination system comprising a plurality of fully addressable LEDs, wherein:
each of the fully addressable LEDs is configured to be independently turned on and off, and
the fully addressable LEDs are configured to project actinic energy through the bottom surface of the vessel to cure selected regions of the liquid photopolymer in the vessel; and
an LCD screen arranged between the backlight illumination system and the bottom surface of the vessel, the LCD screen configured to selectively pass through light generated by the backlight illumination system towards the vessel.

11. The device of claim 10, wherein the fully addressable LEDs are controlled by a LED drive current control of up to 16 bits.

12. A method for fabricating an object using an additive fabrication device, the method comprising:
placing a build platform in the additive fabrication device;
filling a vessel with a liquid photopolymer, wherein the vessel includes a bottom surface transparent to at least a first wavelength of light;
operating a backlight illumination system comprising a plurality of fully addressable LEDs, wherein:
each of the fully addressable LEDs is independently turned on and off, and
the fully addressable LEDs project actinic energy through the bottom surface of the vessel to cure selected regions of the liquid photopolymer in the vessel; and
controlling an LCD screen arranged between the backlight illumination system and the bottom surface of the vessel, the LCD screen selectively passing through light generated by the backlight illumination system towards the vessel, wherein the selective passing of light corresponds to a pattern for forming a layer of the object.

13. A computer-readable medium storing instructions that, when executed by a processor, cause the processor to control an additive fabrication device to perform a method for fabricating an object, the method comprising:
placing a build platform in the additive fabrication device;
filling a vessel with a liquid photopolymer, wherein the vessel includes a bottom surface transparent to at least a first wavelength of light;
operating a backlight illumination system comprising a plurality of fully addressable LEDs, wherein:
each of the fully addressable LEDs is independently turned on and off, and
the fully addressable LEDs project actinic energy through the bottom surface of the vessel to cure selected regions of the liquid photopolymer in the vessel; and
controlling an LCD screen arranged between the backlight illumination system and the bottom surface of the vessel, the LCD screen selectively passing through light generated by the backlight illumination system towards the vessel, wherein the selective passing of light corresponds to a pattern for forming a layer of the object.

14. An additive fabrication device comprising:
a build platform;
a vessel configured to hold a liquid photopolymer;
a backlight illumination system configured to project actinic energy onto the liquid photopolymer and thereby cure selected regions the photopolymer;
an LCD screen arranged between the backlight illumination system and the vessel configured to selectively pass portions of actinic energy projected by the backlight illumination system, wherein the LCD screen includes a first polarizer on a first surface and a second polarizer on a second surface; and
a third polarizer arranged between the backlight illumination system and the first polarizer of the LCD screen.

15. The device of claim 14, wherein the third polarizer is an iodine-type polarizer film, an organic dye-type polarizer film, a wire grid polarizer, a thin film polarizer, or a reflective polarizer.

16. The device of claim 14, wherein the backlight illumination system includes a number of LED light sources, and wherein a polarizing beam splitter, a halfway plate, or a mirror is located between each LED light source and the first polarizer of the LCD screen to rotate cross-polarized light 90 degrees to become parallel polarized light before reaching the first polarizer of the LCD screen.

17. The device of claim 14, wherein the backlight illumination system includes a laser light source, and wherein the laser light source is rotated such that only parallel polarized light impinges on the first polarizer of the LCD screen.

18. The device of claim 14, wherein the backlight illumination system includes a super-luminescent diode rotated such that only parallel polarized light impinges on the first polarizer of the LCD screen.

19. An additive fabrication device comprising:
a build platform;
a vessel configured to hold a liquid photopolymer;
a backlight illumination system configured to project actinic energy onto the liquid photopolymer and thereby cure selected regions the photopolymer;
an LCD screen arranged between the backlight illumination system and the vessel configured to selectively pass portions of actinic energy projected by the backlight illumination system, wherein the LCD screen includes a second polarizer on a second surface; and
a third polarizer arranged between the backlight illumination system and the second polarizer of the LCD screen.
